(19) United States
(12) Patent Application Publication
(10) Pub. No.: US 2008/0318156 A1
(43) Pub. Date: Dec. 25, 2008

(54) Adamantane Based Molecular Glass Photoresists for Sub-200 Nm Lithography

(76) Inventors: Shinji Tanaka, Yamaguchi (JP); Christopher K. Ober, Ithaca, NY (US)

Correspondence Address: MILLER, MATTHIAS & HULL, ONE NORTH FRANKLIN STREET, SUITE 2350, CHICAGO, IL, 60606, US

(21) Appl. No.: 12/162,089

(22) PCT Filed: Feb. 16, 2006
(86) PCT No.: PCT/US06/05378

§ 371 Date: Jul. 24, 2008

(51) Int. Cl. G03C 1/73; G03F 7/20

(52) U.S. Cl. 430/270.1; 430/325

(57) ABSTRACT

Disclosed are glass photoresists generated from adamantane derivatives containing acetal and/or ester moieties as novel high-performance photoresist materials. Some of the disclosed adamantane-based glass resists have a tripodal structure and other disclosed adamantane-based glass resists include one or more cholic groups. The disclosed adamantane derivatives can be synthesized from starting materials which are commercially available. By way of example only, one of many disclosed amorphous glass photoresists has the following structure:

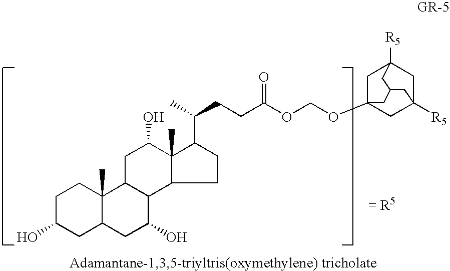

### BACKGROUND

1. Technical Field

Amorphous glass photoresists that are adamantine-based with acetal and/or ester moieties are disclosed for use in sub-200 nm wavelength exposures. The disclosed photoresists reduce variations in line width roughness (LWR) and line edge roughness (LER) at smaller dimensions

2. Description of the Related Art

To meet the requirements for faster performance, integrated circuit devices continue to get smaller and smaller. The manufacture of integrated circuit devices with smaller features introduces new challenges in many of the fabrication processes conventionally used in semiconductor fabrication. One fabrication process that is particularly impacted is photolithography.

In semiconductor photolithography, photosensitive films in the form of photoresists are used for transfer of images to a substrate. A coating layer of a photoresist is formed on a substrate and the photoresist layer is then exposed through a photomask to a source of activating radiation. The photomask has areas that are opaque to activating radiation and other areas that are transparent to activating radiation. Exposure to activating radiation provides a photoinduced chemical transformation of the photoresist coating to thereby transfer the pattern of the photomask to the photoresist-coated substrate. Following exposure, the photoresist is developed to provide a relief image that permits selective processing of a substrate.

A photoresist can be either positive-acting or negative-acting. With a negative-acting photoresist, the coating layer portions that are exposed to the activating radiation polymerize or crosslink in a reaction between a photoactive compound and polymerizable reagents of the photoresist composition. Consequently, the exposed portions of the negative photoresist are rendered less soluble in a developer solution than unexposed portions. In contrast, with a positive-acting photoresist, the exposed portions are rendered more soluble in a developer solution while areas not exposed remain less soluble in the developer.

Chemically-amplified-type resists are used for the formation of sub-micron images and other high performance, smaller sized applications. Chemically-amplified photoresists may be negative-acting or positive-acting and generally include many crosslinking events (in the case of a negative-acting resist) or deprotection reactions (in the case of a positive-acting resist) per unit of photogenerated acid (PGA). In the case of positive chemically-amplified resists, certain cationic photoinitiators have been used to induce cleavage of certain “blocking” groups from a photoresist binder, or cleavage of certain groups that comprise a photoresist binder backbone. Upon cleavage of the blocking group through exposure of a chemically-amplified photoresist layer, a polar functional group is formed, e.g., carboxyl or imide, which results in different solubility characteristics in exposed and unexposed areas of the photoresist layer.

While suitable for many applications, currently available photoresists have significant shortcomings, particularly in high performance applications, such as formation of sub-half micron (<0.5 μm) and sub-quarter micron (<0.25 μm) patterns. Currently available photoresists are typically designed for imaging at relatively higher wavelengths, such as G-line (436 nm), 1-line (365 nm) and KrF laser (248 nm) are generally unsuitable for imaging at short wavelengths such as sub-200 nm. Even shorter wavelength resists, such as those effective at 248 nm exposures, also are generally unsuitable for sub-200 nm exposures, such as 193 nm. For example, current photoresists can be highly opaque to short exposure wavelengths such as 193 nm, thereby resulting in poorly resolved images.

Further, an increased use of such short exposure wavelengths is inevitable as shorter wavelengths are needed for formation of smaller patterns (<0.50 or <0.25). Accordingly, a photoresist that yields well-resolved images upon 193 nm exposure enables formation of small features (<0.25 μm) in response to demands for smaller circuit patterns, greater circuit density and enhanced circuit performance.

As a result, improved photoresists for use with ArF exposure tools (193 nm) are needed and consequently, research is underway to find photoresists that can be photoimaged with short wavelength radiation, including exposure radiation of 200 nm or less, such as a 193 nm wavelength (provided by an ArF exposure tool).

### SUMMARY OF THE DISCLOSURE

Disclosed are glass photoresists generated from adamantane derivatives containing acetal and/or ester moieties as novel high-performance photoresist materials. The term “acetal and/or ester moieties” will hereinafter mean at least one acetal moiety or at least one ester moiety or a combination of at least one acetal moiety and at least one ester moiety or a combination of one or more acetal moieties and one or more ester moieties.

In a refinement, adamantane core derivatives of a tripodal structure are also disclosed. As alternatives, four-branch structures are disclosed and more than four branches are envisioned

The disclosed adamantane derivatives can be synthesized from starting materials which are commercially available.

In a refinement, the glass photoresists may selected from the following general structures as well as other adamantane based structures with acetal and/or ester moieties:

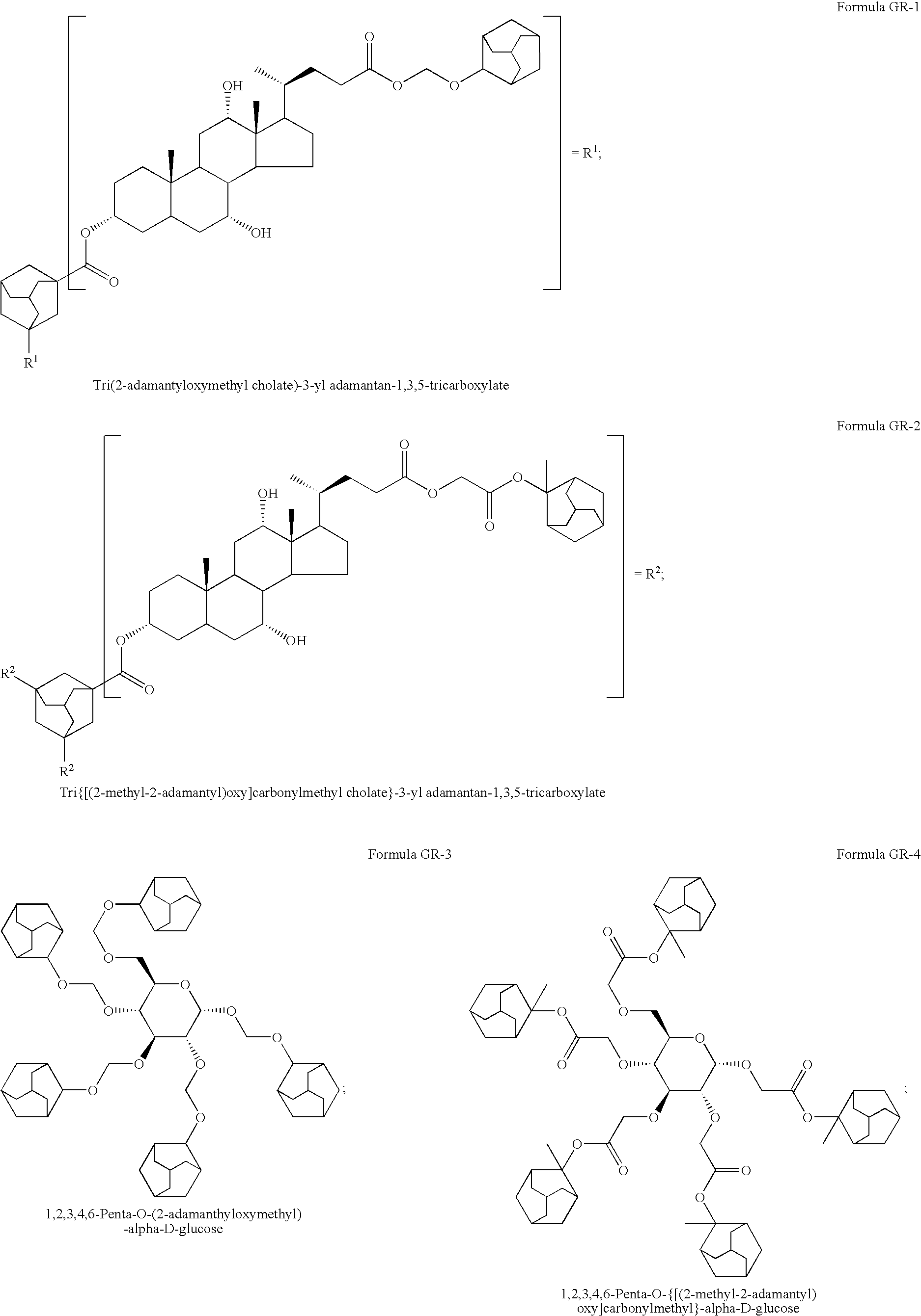

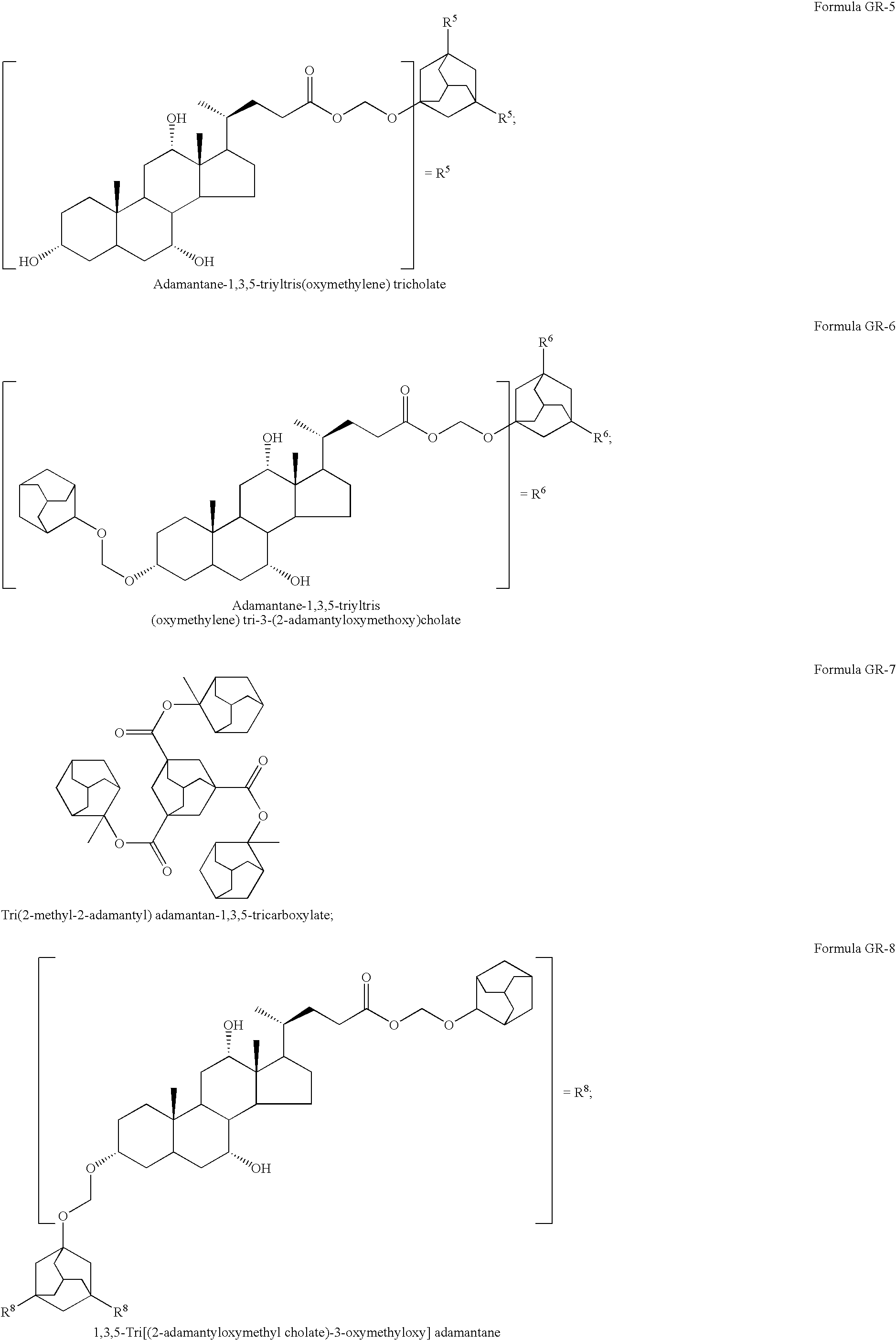

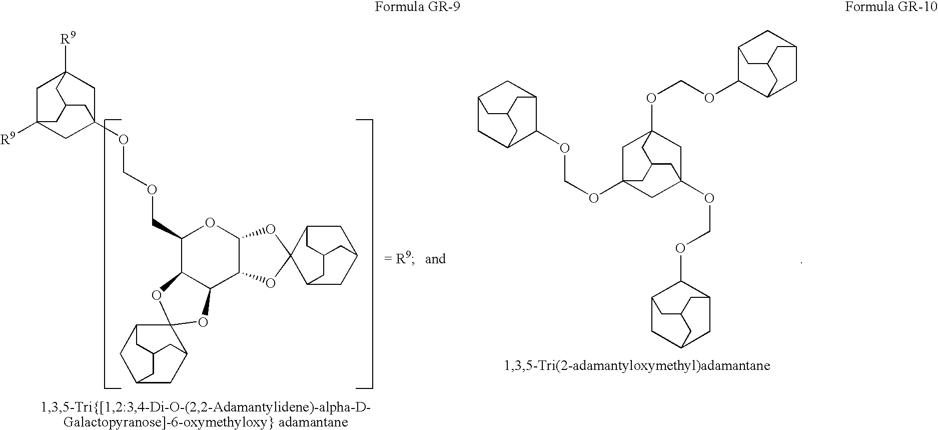

Again, other adamantane structure with acetal and/or ester moieties will be apparent to those skilled in the art and the above list is not meant to be exhaustive.

The disclosed photoresist glasses may be synthesized from precursors selected from the group consisting of:

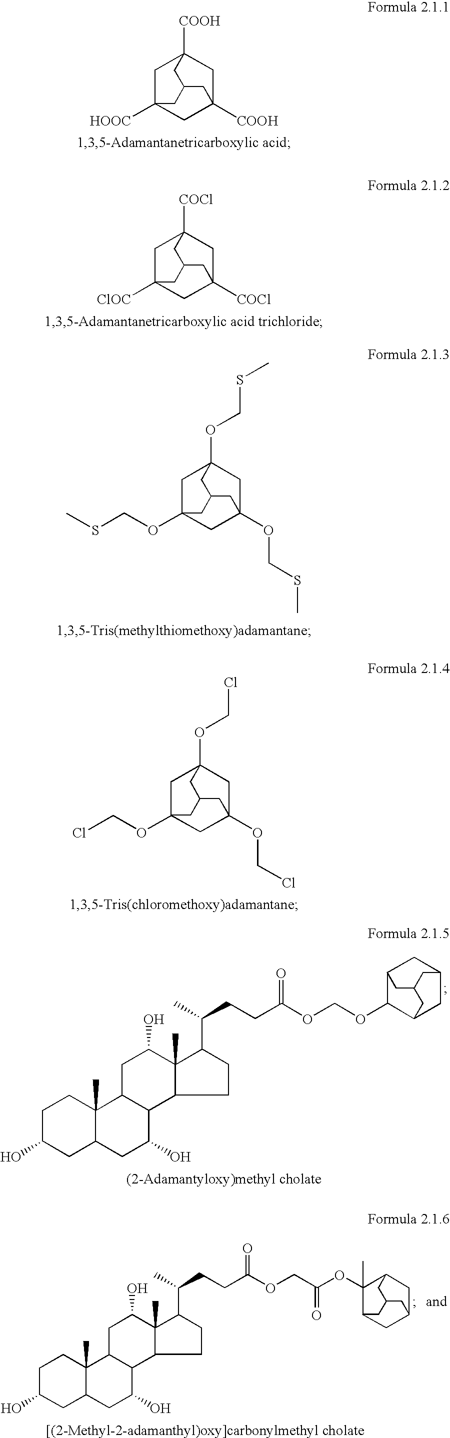

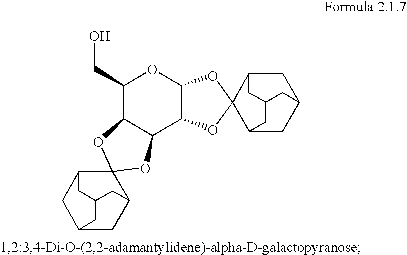

as well as commercially available materials including, but not limited to

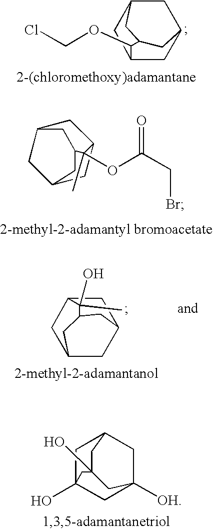

Reagents used for converting the precursors to the amorphous glass photoresists include triethylamine (TEA), dimethylsulfoxide (DMSO) and n-butyl lithium.

Synthesis of the non-commercially available precursors (2.1.1-2.1.7) is described below. Again, other possible precursors for the synthesis of adamantane based glasses with acetal and/or ester moieties will be apparent to those skilled in the art and the above list is not meant to be exhaustive.

### BRIEF DESCRIPTION OF THE FIGURES

The disclosed photoresists, synthetic methods and lithographic methods described in greater detail below in conjunction with the following figures, wherein:

FIG. 1 presents physical properties of ten disclosed photoresists in tabular form;

FIG. 2 graphically illustrates thermal properties of the photoresist illustrated in Formula GR-1;

FIG. 3 graphically illustrates thermal properties of the photoresist illustrated in Formula GR-2;

FIG. 4 graphically illustrates thermal properties of the photoresist illustrated in Formula GR-5;

FIG. 5 graphically illustrates thermal properties of the photoresist illustrated in Formula GR-9;

FIG. 6 presents, in tabular form, the experimental conditions for the pattern imaging data presented in FIG. 7;

FIG. 7 are three exposure images of the photoresist illustrated in Formula GR-5 including two optical microscope images and a 200 nm line/space SEM image;

FIG. 8 graphically illustrates exposure sensitivity of the photoresist illustrated in Formula GR-5;

FIG. 9 presents, in tabular form, etch rates for the photoresists illustrated in Formulas GR-1 and GR-5;

FIG. 10 illustrates, graphically, etch rates for the photoresists illustrated in Formulas GR-1 and GR-5; and

FIG. 11 illustrates, graphically, a correlation between etch rates and Ohnishi Parameter (N_{T}/N_{C}−N_{O}) for the photoresists illustrated in Formulas GR-1 and GR-5.

It should be understood, of course, that this disclosure is not limited to the particular embodiments illustrated herein.

### DETAILED DESCRIPTION OF THE PRESENTLY PREFERRED EMBODIMENTS

The disclosure related to low molecular weight photoresist materials that form stable glasses above room temperature. The disclosed photoresists offer several advantages over traditional linear polymers as patterning feature size decreases. First, the disclosed materials are amorphous and have low molecular weight. As a result, they are free from chain entanglements. Because the disclosed materials have smaller molecular sizes and higher densities of sterically congested peripheral molecules, the disclosed photoresists are expected to reduce the variations in line width roughness (LWR) and line edge roughness (LER) at smaller design dimensions.

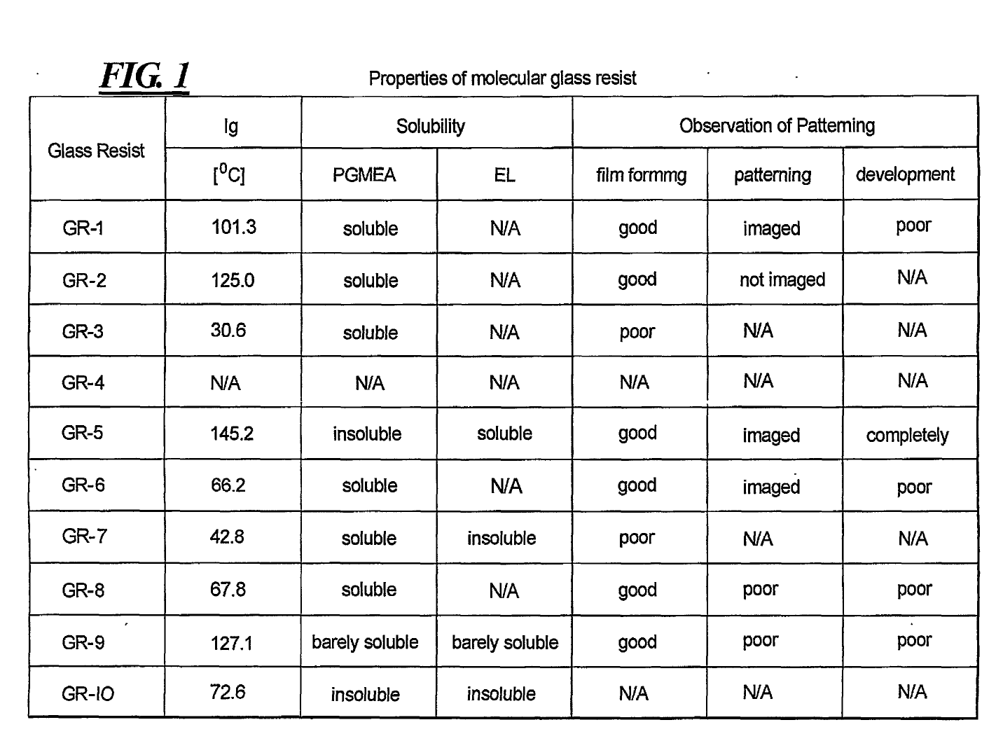

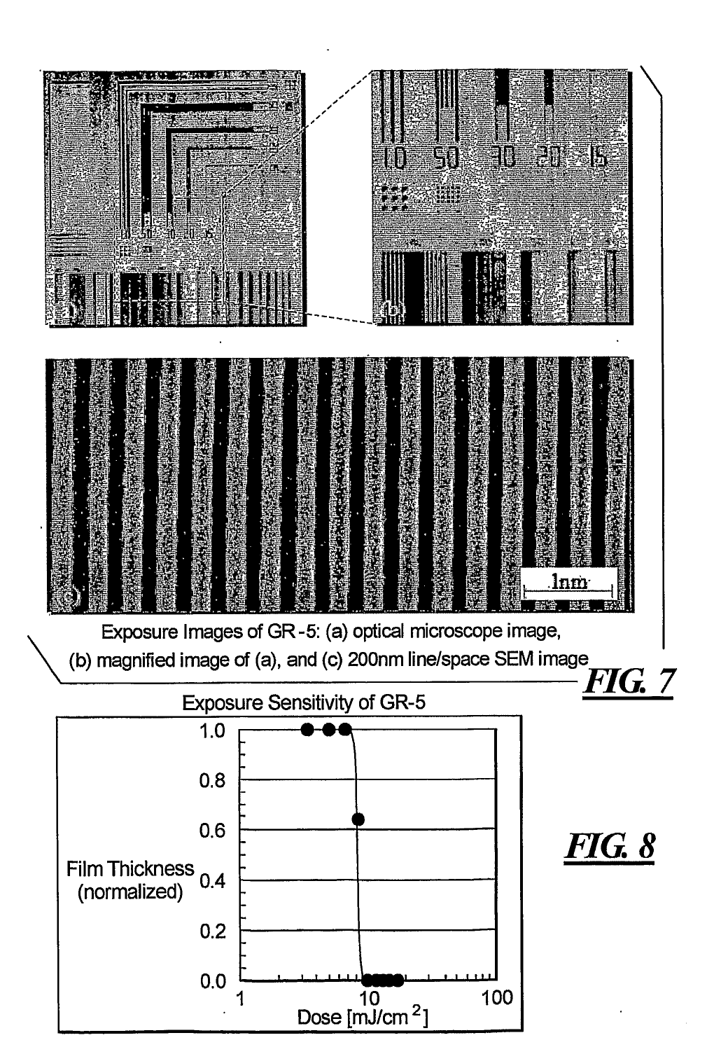

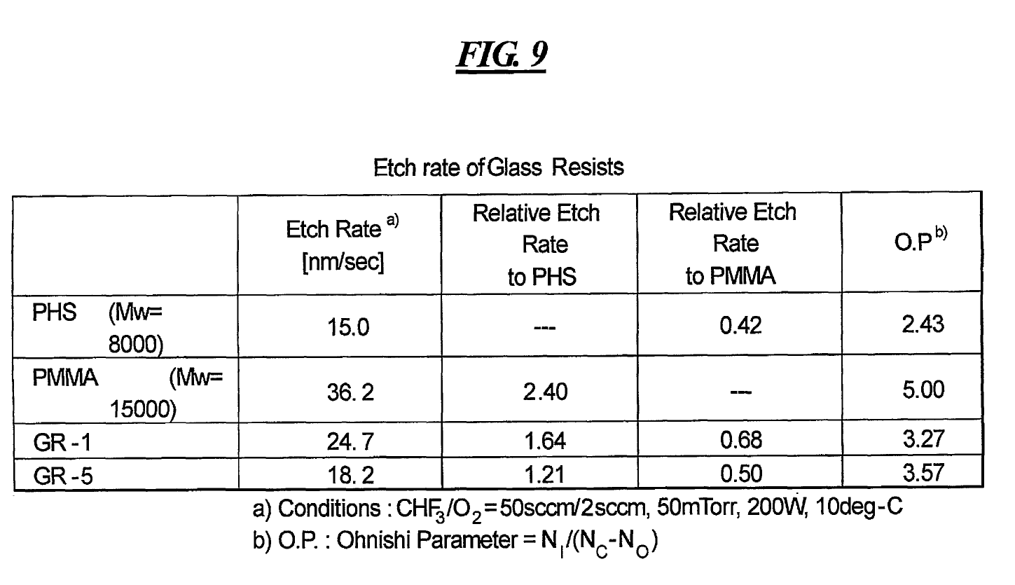

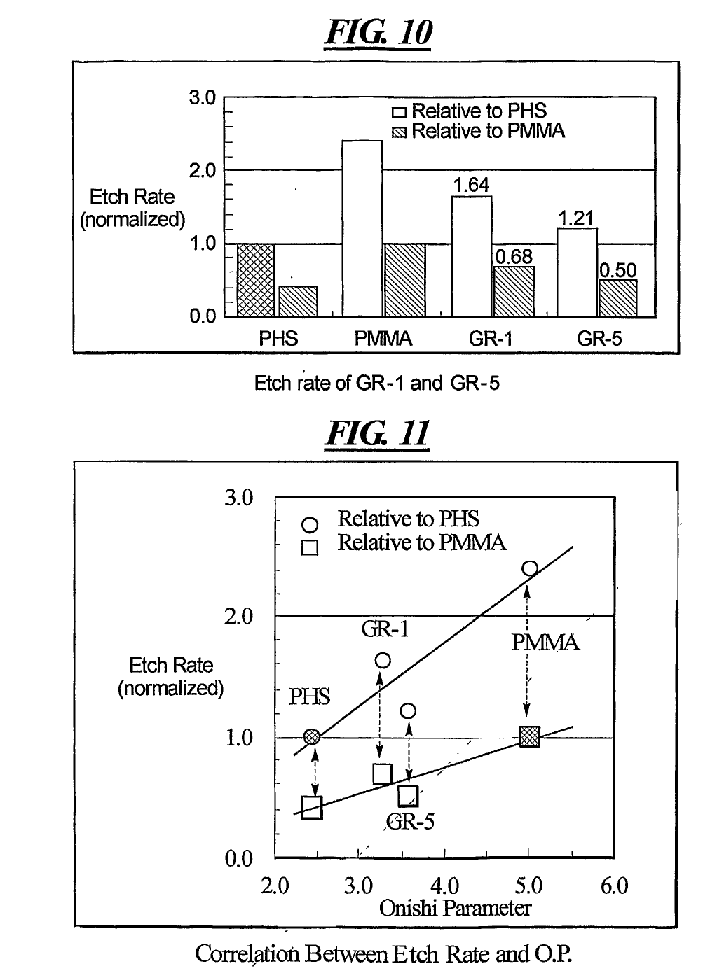

In addition, the small uniform molecular size offers excellent processability, flexibility, transparency and uniform dissolution properties. Any photoresist material used for 193 nm or immersion 193 nm exposures must have high plasma-etch resistance and superior optical as well as materials properties for improved lithographic performance. Higher carbon to hydrogen ratio and non-aromatic groups in the resist improves the etch resistance and transparency. As a result the disclosed low molecular weight adamantane derivatives containing acetal and ester moieties provide high-performance as photoresist materials. Particularly, adamaitane core derivatives of tripodal structure are shown to be particularly effective below. Several examples of them showed high glass transition temperatures (Tg) above 120° C. (FIG. 1) and imaged feature size as small as 200 nm in line/space patterns on positive tone lithography (FIG. 7). Furthermore, high plasma-etch resistances and high dose sensitivities have been confirmed (FIGS. 9-11).

As noted above, the amorphous glass photoresists are adamantane based. The non-commercially available precursors represented by the Formulas 2.1.1-2.1.7 used in the synthesis of the photoresists are, in turn, synthesized as follows:

### Synthesis of Precursors for Molecular Glass Resists

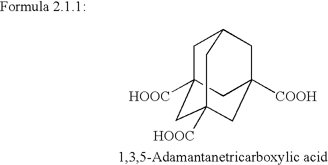

Adamantanetriol [917 mg, 5.0 mmol] was dissolved in sulfuric acid, 20% fuming [50 mL] at room temperature. The solution was stirred and heated at 50deg.-C. Formic acid [10 mL, 265 mmol] was added drop wise into the solution for 50 min, then gas generated intensely and the solution turned pale yellow. After stirring for 16 hours, the solution was added into water [400 mL], then white precipitation generated gradually. The mixture was filtered by glass filter and washed by water [50 mL] three times. The washed white precipitation was dried in vacuo, then white powder was obtained [679 mg, 2.5 mmol, isolated yield: 50.9%]. ¹H-NMR: 1.70 (s, 6H), 1.76 (d, J=13.2 Hz, 3H), 1.86 (d, J=12.6 Hz, 3H), 2.17 (s, 1H), 12.3 (br-s, 3H). ¹³C-NMR: 27.54, 36.84, 39.07, 40.31, 177.37.

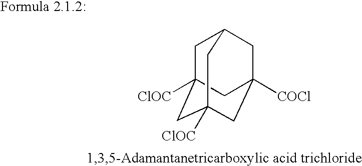

Thionyl chloride [30.0 mL, 41 mmol] was added in the powder of 1,3,5-Adamantanetricarboxylic acid [4288 mg, 16.0 mmol] (Formula 2.1.1) under a nitrogen atmosphere. The resulting slurry was dissolved gradually and turned to brown solution. Then the solution was heated and refluxed for 3 hours. The excess thionyl chloride was evaporated by the bulb-to-bulb technique at 90° C. in vacuo. The products was dried in vacuo without further purification, then white-brown crystals was obtained [4158 mg, 12.8 mmol, isolated yield: 80.4%]. ¹H-NMR: 2.00 (d, J=1.8 Hz, 6H), 2.18 (d, J=12.9 Hz, 3H), 2.28 (d, J=12.7 Hz, 3H), 2.56 (quintet, J=3.0 Hz, 1H). ¹³C-NMR: 27.79, 36.73, 38.99, 51.29, 177.33.

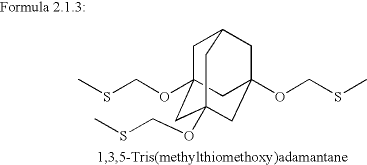

1,3,5-Adamanntanetriol [11.06 g, 60.0 mmol] was dissolved in the mixture of dimethylsulfoxide [120 mL, 1691 mmol] and acetic anhydride [60 mL, 636 mmol]. The solution was stirred for 20 hours, then added to aqueous NaOH solution [100 mL, 49.40 g as NaOH, 1235 mmol]. The mixture was extracted by diethyl ether [100 mL] four times. The extracted solution was washed by saturated aqueous NaCl solution [30 mL] three times, and dried over anhydrous Na₂SO₄. The solution was filtered by a paper filter and concentrated. After volatility was distilled at 120° C. in vacuo, the colorless clear oil was obtained as residue [8.09 g, 22.2 mmol, isolated yield: 37.0%]. ¹H-NMR: 1.48˜1.55 (m, 3H), 1.56˜1.65 (m, 6H), 1.71˜1.76 (m, 3H), 2.11 (s, 9H), 2.16 (s, 1H), 4.52 (s, 6H). ¹³C-NMR: 14.19, 29.06, 42.76, 48.26, 66.28, 76.30.

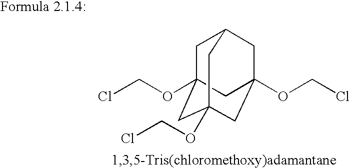

1,3,5-tris(methylthiomethoxy)adamantane [8.09 g, 22.2 mmol] was dissolved in dry dichloromethane [30 mL] under a nitrogen atmosphere. Thionyl chloride [7.0 mL, 96.2 mmol] was diluted by dry dichloromethane [20 mL] in nitrogen atmosphere, then the dilution was added drop wise for 5 min into the solution. The solution turned white-yellow slurry and generated heat for 5 min. After while the solution turned clear yellow solution and gas generated for 40 min. The solution was stirred for 3 h totally, the excess thionyl chloride was evaporated by the bulb-to-bulb technique at 90° C. in vacuo. The products was dried in vacuo without further purification, then the product of high viscous yellow oil was obtained [7.40 g, 22.4 mmol, isolated yield quantity.]. ¹H-NMR: 1.81 (d, J=3.3 Hz), 2.04 (s, 6H), 2.28 (s, 1H), 5.60 (s, 6H). ¹³C-NMR: 28.81, 39.09, 45.25, 75.67, 78.71.

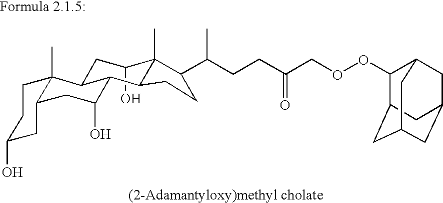

Cholic acid [8.46 g, 20.7 mmol] and 2-(chloromethoxy)adamantane (“Adamantate AOMC-2” manufactured by Idemitsu Kosan Co., Ltd.) [4.57 g, 22.8 mmol] were dissolved in dry tetrahydrofuran [60 mL] under a nitrogen atmosphere. After being the clear solution, triethyl amine [4.7 mL, 33.7 mmol] was added drop wise to the solution to form a white precipitation and heat. After stirring for 16 hours, the reaction was quenched by water. The mixture was extracted by diethyl ether [100 mL] three times. The extracted solution was concentrated at once, added diethyl ether. Following the solution was washed by water [50 mL] three times and by saturated aqueous NaCl solution [50 mL] once, and dried over anhydrous Na₂SO₄. The solution was filtered by a paper filter and concentrated. After drying in vacuo, then the product of white powder was obtained [11.15 g, 19.5 mmol, isolated yield: 94.0%]. ¹H-NMR: 0.67 (s, 3H), 0.88 (s, 3H), 0.98 (d, J=6.3 Hz, 3H), 1.05˜2.45 (m, 36H), 2.65 (br-s, 3H), 3.39˜3.49 (m, 2H), 3.72˜3.76 (m, 2H), 3.84 (m, 1H), 3.96 (m, 1H), 5.35 (s, 2H). ¹³C-NMR: 12.40, 17.26, 22.46, 23.20, 25.58, 26.41, 27.09, 27.28, 27.45, 28.19, 30.40, 30.70, 31.35, 31.50, 32.37, 34.60, 34.71, 35.20, 36.46, 37.42, 39.47, 41.42, 41.72, 46.43, 47.07, 67.94, 68.43, 71.93, 73.03, 82.34, 87.70, 173.90.

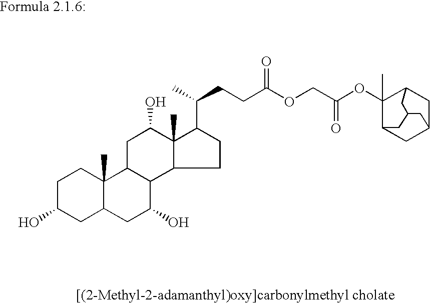

Cholic acid [8.17 g, 20.0 mmol] and 2-methyl-2-adamantyl bromoacetate (“Adamantate BRMM” manufactured by Idemitsu Kosan Co., Ltd.) [6.32 g, 22.0 mmol] were dissolved in dry tetrahydrofuran [60 mL] under a nitrogen atmosphere. After being the clear solution, triethyl amine [4.1 mL, 29.4 mmol] was added drop wise and a white precipitation generated gradually. The solution was stirred only slightly because of the ongoing precipitation. Diethyl ether [20 mL] was subsequently added. After stirring for 16 hours, the reaction was quenched by water. The mixture was concentrated at once and added diethyl ether. The mixture was extracted by diethyl ether [50 mL] three times. The extracted solution was washed by water [50 mL] three times and by saturated aqueous NaCl solution [50 mL] once, and dried over anhydrous Na₂SO₄. The solution was filtered by a paper filter and concentrated. Then colorless clear oil was purified by re-precipitation of diethyl ether/n-hexane system. Finally white powder was obtained after drying in vacuo [6.04 g, 9.8 mmol, isolated yield: 49.1%]. ¹H-NMR: 0.66 (s, 3H), 0.87 (s, 3H), 0.97 (d, J=6.0 Hz, 3H), 1.21˜1.57 (m, 10H), 1.61 (s, 3H), 1.69˜2.52 (m, 26H), 2.81 (br-s, 3H), 3.38˜3.48 (m, 1H), 3.71˜3.79 (m, 2H), 3.83 (m, 1H), 3.94 (m, 1H), 4.53 (s, 2H). ¹³C-NMR: 12.43, 17.29, 22.03, 22.26, 22.43, 23.18, 25.56, 26.35, 26.49, 27.19, 27.41, 27.50, 28.15, 30.35, 30.61, 30.78, 32.86, 34.44, 34.60, 34.71, 35.16, 35.21, 36.06, 36.16, 38.00, 39.45, 41.43, 41.64, 46.41, 46.92, 60.89, 67.92, 68.41, 71.94, 73.00, 89.08, 166.62, 173.58.

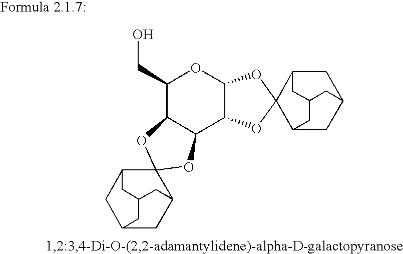

2-Adamantanone [9.01 g, 60 mmol] and D-(+)-galactose [5.41, 30 mmol] were dissolved in dry tetrahydrofuran [90 mL] under nitrogen atmosphere. Zinc chloride [16.41 g, 120 mmol] was added into the solution, then heat generated slightly. 98% Sulfuric acid [1.5 mL] was added into the solution, it turned from white slurry to clear solution gradually. After stirring for 20 hours, the reaction was quenched by aqueous K₂CO₃ solution [100 mL, 33.40 g as K₂CO₃, 242 mmol]. The mixture was extracted by tetrahydrofuran [200 mL] three times. The extracted solution was washed by saturated aqueous NaCl solution [50 mL] three times, and dried over anhydrous Na₂SO₄. The solution was filtered by a paper filter and concentrated. After re-crystallization of tetrahydrofuran, white powder was obtained [9.31, 20.9 mmol, isolated yield: 69.8%]. ¹H-NMR: 1.52˜2.23 (m, 28H), 3.69˜3.81 (m, 2H), 3.82˜3.94 (m, 2H), 4.27 (dd, J=1.6 Hz, 7.9 Hz, 1H), 4.37 (dd, J=5.0 Hz, 2.4 Hz, 1H), 4.64 (dd, J=2.4 Hz, 7.9 Hz, 1H), 5.58 (d, J=5.0 Hz, 1H). ¹³C-NMR: 26.59, 26.76, 26.84, 26.89, 34.06, 34.36, 34.55, 34.58, 34.83, 34.91, 34.96, 35.00, 35.27, 36.89, 36.96, 37.07, 37.23, 62.59, 67.94, 70.08, 70.43, 71.28, 95.79, 111.55, 112.39.

The successfully synthesized amorphous glass photoresists include:

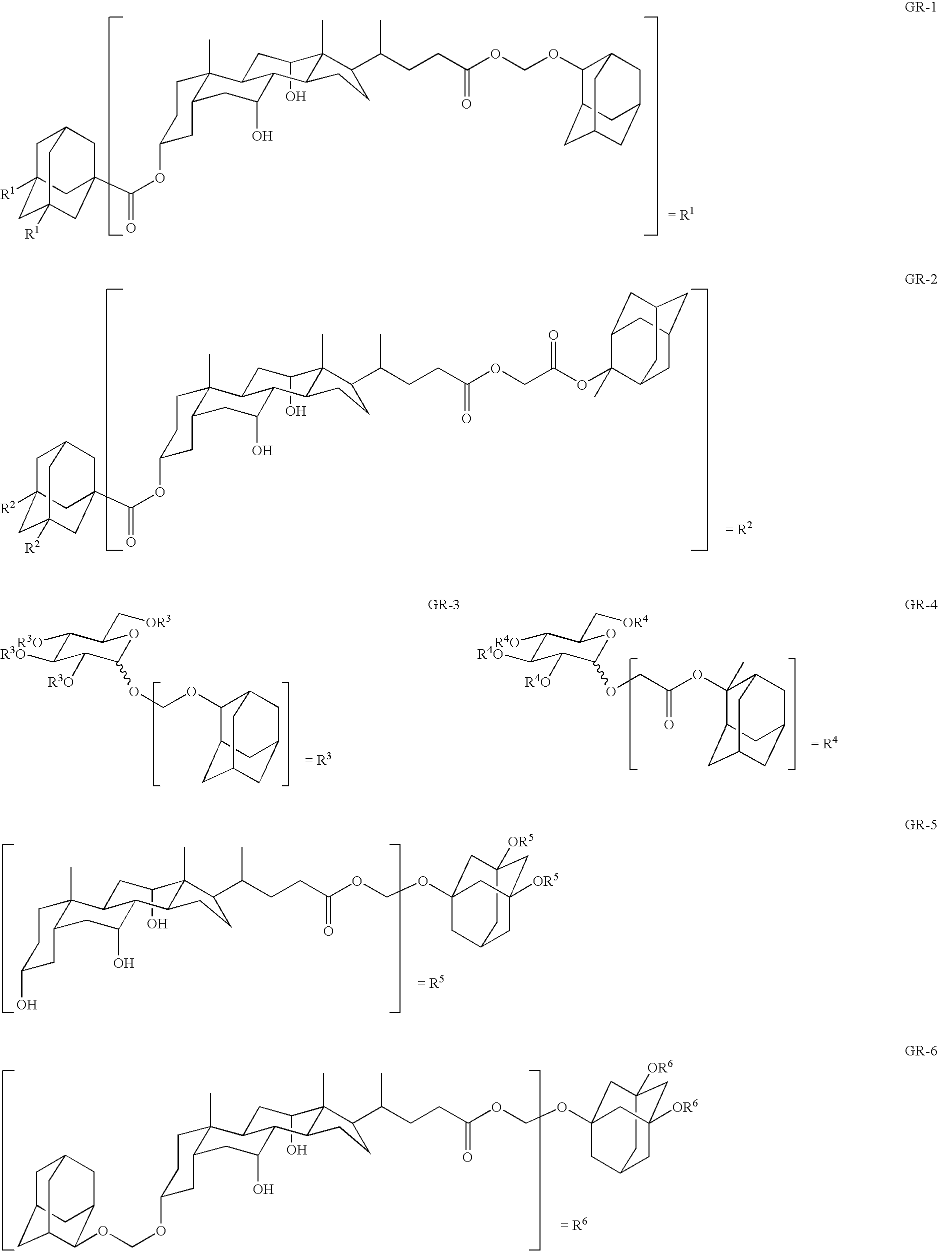

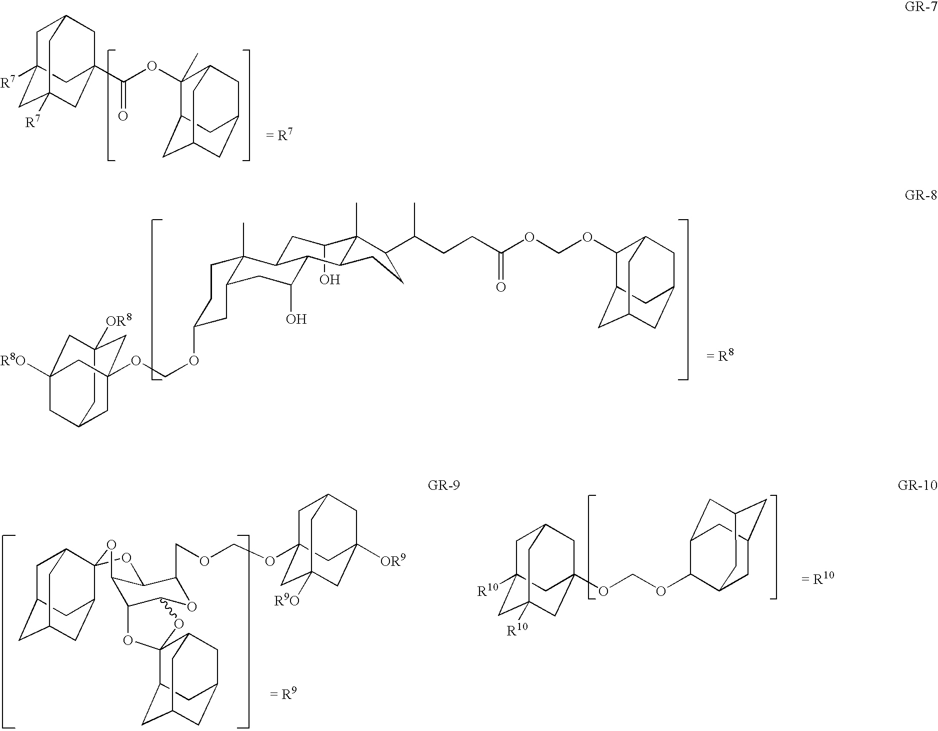

### Synthesis of Glass Photoresists

Synthesis procedures for GR-1 through GR-10 are as follows:

Tri(2-adamantyloxymethyl cholate)-3-yl adamantan-1,3,5-tricarboxylate (Formula GR-1):

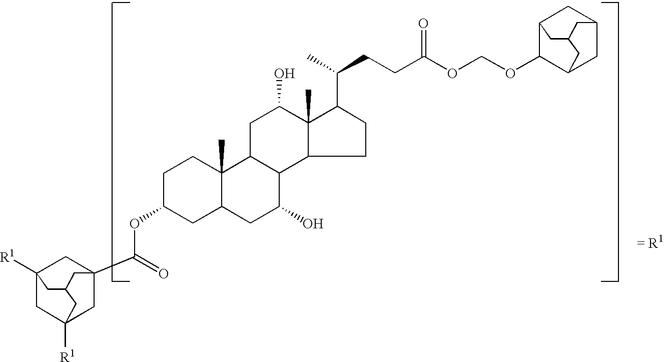

1,3,5-Adamantanetricarboxylic acid trichloride [162 mg, 0.50 mmol] (Formula 2.1.2) and (2-Adamantyloxy)methyl cholate [945 mg, 1.65 mmol] (Formula 2.1.6) were dissolved in dry tetrahydrofuran [10 mL] under nitrogen atmosphere. Triethyl amine [0.31 mL, 2.25 mmol] was added drop wise, while a white precipitation was generated. After stirring for 20 hours, the reaction was quenched by water. The mixture was extracted by ethyl acetate [30 mL] three times. The extracted solution was washed by saturated aqueous NaCl solution [30 mL] once, and dried over anhydrous Na₂SO₄. The solution was filtered by a paper filter and concentrated. The product was obtained as white powder after drying in vacuo [984 mg, 0.51 mmol, isolated yield quantity.]. ¹H-NMR: 0.66 (s, 9H), 0.87 (s, 9H), 0.97 (d, J=5.4 Hz, 9H), 1.05˜2.45 (m, 121H), 2.95˜3.55 (m, 12H), 3.72 (m, 3H), 3.83 (m, 3H), 3.96 (m, 3H), 4.54 (m, 3H), 5.34 (s, 6H). ¹³C-NMR: 12.41, 14.14, 17.21, 21.00, 22.42, 23.17, 26.31, 26.57, 27.05, 27.24, 27.44, 28.09, 30.32, 30.66, 31.31, 31.47, 31.58, 32.33, 34.60, 34.68, 34.86, 35.20, 36.42, 36.55, 37.38, 37.52, 39.04, 39.40, 40.95, 41.17, 41.39, 41.62, 41.97, 46.37, 46.41, 47.01, 47.14, 60.35, 68.18, 68.26, 68.41, 71.85, 72.22, 72.88, 73.04, 82.34, 87.65, 173.92, 175.60, 175.64, 175.87. MALDI/TOF-MS: 1954 (78%, M⁺−H⁺+Na⁺), 1400 (100%).

Tri{[(2-methyl-2-adamantyl)oxy]carbonylmethyl cholate}-3-yl adamantan-1,3,5-tricarboxylate (Formula GR-2):

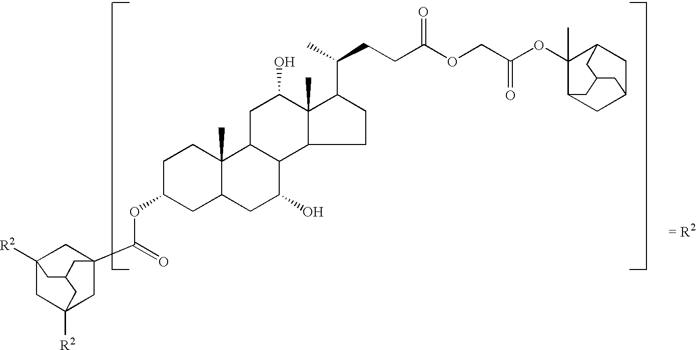

1,3,5-Adamantanetricarboxylic acid trichloride [162 mg, 0.50 mmol] (Formula 2.1.2) and [(2-Methyl-2-adamantyl)oxy]carbonylmethyl cliolate [1015 mg, 1.65 mmol] (Formula 2.1.6) were dissolved in dry tetrahydrofuran [10 mL] under a nitrogen atmosphere. Triethyl amine [0.31 mL, 2.25 mmol] was added drop wise to produce a white precipitation. After stirring for 20 hours, the reaction was quenched by water. The mixture was extracted by ethyl acetate [30 mL] three times. The extracted solution was washed by saturated aqueous NaCl solution [30 mL] once, and dried over anhydrous Na₂SO₄. The solution was filtered by a paper filter and concentrated. The product was obtained as white powder after drying in vacuo [569 mg, 0.28 mmol, isolated yield: 55.2%]. ¹H-NMR: 0.69 (s, 9H), 0.89 (s, 9H), 0.99 (d, J=5.6 Hz, 9H), 1.20˜1.61 (m, 91H), 1.63 (s, 9H), 1.64˜2.40 (m, 33H), 2.65 (br-s, 6H), 3.42˜3.52 (m, 3H), 3.86 (m, 3H), 3.99 (m, 3H), 4.02 (m, 3H), 4.55 (s, 6H). ¹³C-NMR: 12.41, 17.25, 22.13, 22.24, 22.42, 23.16, 26.47, 27.15, 27.39, 27.91, 28.11, 28.34, 30.24, 30.33, 30.57, 30.73, 32.86, 34.43, 34.67, 34.77, 35.12, 35.21, 36.03, 36.14, 37.93, 37.98, 39.36, 39.41, 40.93, 41.03, 41.16, 41.41, 41.66, 41.85, 46.39, 46.91, 47.04, 60.88, 68.15, 68.40, 71.91, 72.85, 73.01, 74.12, 89.10, 89.76, 166.63, 173.58, 175.54, 175.64, 175.89.

1,2,3,4,6-Penta-O-(2-adamanthyloxymethyl)-α-D-glucose (Formula GR-3)

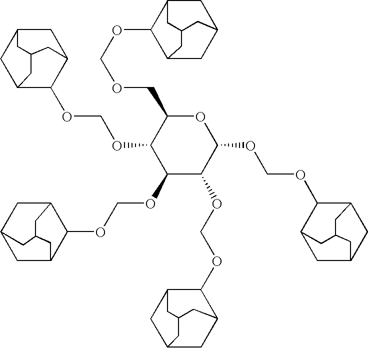

D-(+)-Glucose [180 mg, 1.0 mmol] and 2-(chloromethoxy)adamantane (“Adamantate AOMC-2” manufactured by Idemitsu Kosan Co., Ltd.) [1104 mg, 5.5 mmol] were dissolved in dry tetrahydrofuran [10 mL] and dimethylsulfoxide [5 mL] under nitrogen atmosphere. K₂CO_{3 [}1037 mg, 7.5 mmol] was added into the solution. After stirring for 18 hours, triethyl amine [1.05 mL, 7.5 mmol] was added into the solution. After stirring for 1 day, the generated precipitation was filtered by a paper filter. After evaporation, diethyl ether was added into the solution, then the solution was separated two layers. The solution was washed by water [50 mL] six times totally, and dried over anhydrous K₂CO₃. The solution was filtered by a paper filter and concentrated. The product was obtained as white powder after drying in vacuo [843 mg, 0.84 mmol, isolated yield: 84.3%]. ¹H-NMR: 1.37˜2.18 (m, 70H), 3.27˜4.11 (m, 11H), 4.51˜5.40 (m, 11H). MALDI/TOF-MS: 787 (100%).

1,2,3,4,6-Penta-O-{[(2-methyl-2-adamantyl)oxy]carbonylmethyl}-α-D-glucose (Formula GR-4)

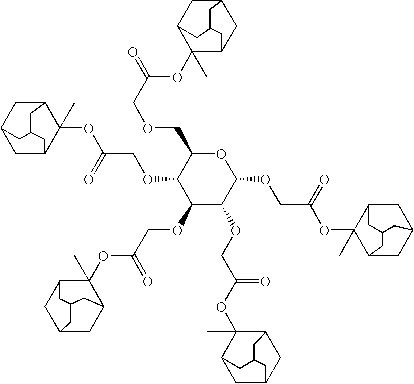

2-Methyl-2-adamantyl bromoacetate (“Adamantate BRMM” manufactured by Idemitsu Kosan Co., Ltd.) [1580 mg, 5.5 mmol] was used instead of 2-(chloromethoxy)adamantane in the same conditions as above for Formula GR-3. Finally, the product was obtained as high viscous oil [290 mg, 0.24 mmol, isolated yield: 24.0%]. ¹H-NMR: 1.49˜2.35 (m, 70H), 1.64 (s, 15H), 3.69˜3.93 (m, 3H), 4.08 (s, 10H), 4.13˜4.24 (m, 2H), 4.53˜4.61 (m, 2H).

Adamantane-1,3,5-triyltris(oxymethylene) tricholate (Formula GR-5)

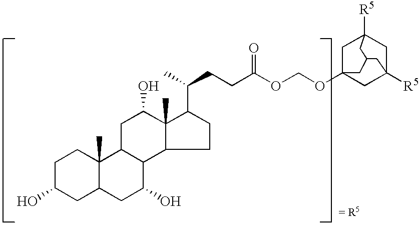

1,3,5-Tris(chloromethoxy)adamantane [1366 mg, 4.14 mmol] (Formula 2.1.4) and cholic acid [5079 mg, 12.4 mmol] were dissolve in dry tetrahydrofuran [40 mL] under a nitrogen atmosphere. Triethyl amine [2.30 mL, 16.5 mmol] was added drop wise, and a white precipitation was generated. After stirring for 5 days, the reaction was quenched by water. The mixture was extracted by diethyl ether [50 mL] three times. The extracted solution was washed by saturated aqueous NaCl solution [30 mL] three times, and dried over anhydrous Na₂SO₄. The solution was filtered by a paper filter and concentrated. The crude mixture was re-precipitated from tetrahydrofuran/diethyl ether system, the product was obtained as white powder after drying in vacuo [2288 mg, 1.58 mmol, isolated yield: 38.2%]. ¹H-NMR: 0.68 (s, 9H), 0.88 (s, 9H), 1.00 (br-s, 9H), 1.26˜2.55 (m, 79H), 3.41 (br-s, 15H), 3.84 (br-s, 3H), 3.97 (br-s, 3H), 4.89 (m, 3H), 5.37 (s, 6H). ¹³C-NMR: 12.27, 16.79, 22.55, 22.74, 26.14, 27.26, 28.46, 30.34, 30.51, 31.04, 34.32, 34.81, 34.92, 35.25, 38.59, 38.87, 39.15, 39.43, 39.71, 39.99, 40.27, 41.30, 41.45, 45.71, 46.12, 66.18, 70.37, 70.93, 76.59, 82.01, 172.64. MALDI/TOF-MS: 1169 (46%), 1139 (100%), 821 (50%), 791 (90%).

Adamantane-1,3,5-triyltris(oxymethylene) tri-3-(2-adamantyloxymethoxy)cholate (Formula GR-6)

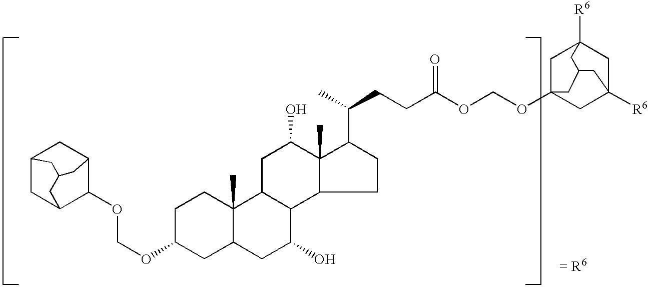

Adamantane-1,3,5-triyltris(oxymethylene) tricholate (Formula GR-5) [723 mg, 0.50 mmol] and 2-(chloromethoxy)adamantane (“Adamantate AOMC-2” manufactured by Idemitsu Kosan Co., Ltd.) [1010 mg, 5.03 mmol] were dissolved in dry tetrahydrofuran [10 mL] under nitrogen atmosphere. Triethyl amine [1.90 mL, 13.6 mmol] was added drop wise, then white precipitation generated immediately. After stirring for 21 hours, the reaction was quenched by water. The mixture was extracted three times by the mixture [50 mL] of diethyl ether and tetrahydrofuran. The extracted solution was washed by saturated aqueous NaCl solution [30 mL] twice, and dried over anhydrous Na₂SO₄. The solution was filtered by a paper filter and concentrated. The crude mixture was re-precipitated from tetrahydrofuran/diethyl ether system, the product was obtained as white powder after drying in vacuo [334 mg, 0.17 mmol, isolated yield: 34.5%]. ¹H-NMR: 0.66 (s, 9H), 0.87 (s, 9H), 0.97 (d, J=3.7 Hz, 9H), 1.24˜2.61 (m, 121H), 3.34 (br-s, 12H), 3.73 (br-s, 3H), 3.82 (br-s, 3H), 3.95 (br-s, 3H), 4.77 (s, 6H), 4.88 (m, 3H), 5.36 (s, 6H).

Tri(2-methyl-2-adamantyl) adamantan-1,3,5-tricarboxylate (Formula GR-7)

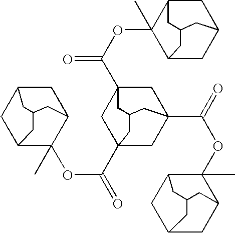

1.6M n-Butyl lithium solution in hexane was added into the dry tetrahydrofuran [20 mL] solution of 2-methyl-2-adamantanol [2494 mg, 15.0 mmol] under nitrogen atmosphere, then the solution turned to white slurry gradually. After stirring for 1.5 hours, the dry tetrahydrofuran [10 mL] solution of 1,3,5-Adamantanetricarboxylic acid trichloride [1618 mg, 5.0 mmol] (Formula 2.1.2) was added drop wise into the solution by a canula. After stirring for 20 hours, the reaction was quenched by water. The mixture was extracted by diethyl ether [50 mL] three times. The extracted solution was washed by water [50 mL] twice and by saturated aqueous NaCl solution [30 mL] once, and dried over anhydrous Na₂SO₄. The solution was filtered by a paper filter and concentrated. The mixture was purified by silica gel chromatography using diethyl ether/n-hexane [1/1] as effluent, then the product was obtained as white crystal after drying in vacuo [2498, 3.50 mmol, isolated yield: 70.1%]. ¹H-NMR: 1.52 (br, 3H), 1.56 (s, 10H), 1.69 (br, 9H), 1.71˜1.87 (m, 21H), 1.88 (br, 3H), 1.96 (br, 3H), 2.01 (br, 9H), 2.29 (br, 6H). ¹³C-NMR: 22.21, 26.70, 27.31, 28.24, 33.05, 34.49, 36.17, 37.41, 38.13, 39.73, 42.36, 86.70, 175.00.

1,3,5-Tri[(2-adamantyloxymethyl cholate)-3-oxymethyloxy]adamantane (Formula GR-8)

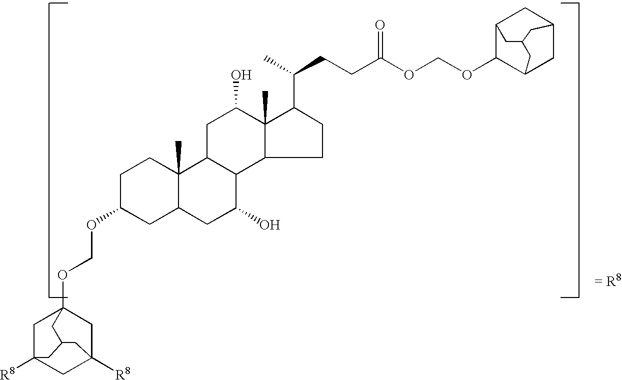

1,3,5-Tris(chloromethoxy)adamantane [665 mg, 2.02 mmol] (Formula 2.1.4) and (2-Adamantyloxy)methyl cholate [3468 mg, 6.05 mmol] (Formula 2.1.5) were dissolved in dry tetrahydrofuran [30 mL] under a nitrogen atmosphere. Triethyl amine [10.1 mL, 7.89 mmol] was added drop wise, then white precipitation generated. After stirring for 2 days, the reaction was quenched by water. The mixture was added diethyl ether [70 mL] and the organic layer was separated. The aqueous layer was extracted twice by the mixture of diethyl ether and tetrahydrofuran [30 mL]. All of the organic solution was washed by saturated aqueous NaCl solution [30 mL] twice, and dried over anhydrous Na₂SO₄. The solution was filtered by a paper filter and concentrated. The crude mixture was re-precipitated from tetrahydrofuran/n-hexane system, the product was obtained as white powder after drying in vacuo [2322 mg, 1.20 mmol, isolated yield: 59.4%]. ¹H-NMR: 0.66 (s, 9H), 0.87 (s, 9H), 0.97 (d, J=5.9 Hz, 9H), 1.18˜2.45 (m, 121H), 3.16˜3.68 (m, 12H), 3.68˜3.79 (m, 6H), 3.83 (m, 3H), 3.96 (m, 3H), 4.61˜4.98 (m, 6H), 5.35 (s, 6H).

1,3,5-Tri{[1,2:3,4-Di-O-(2,2-Adamantylidene)-α-D-Galactopyranose]-6-oxymethyloxy}adamantane (Formula GR-9)

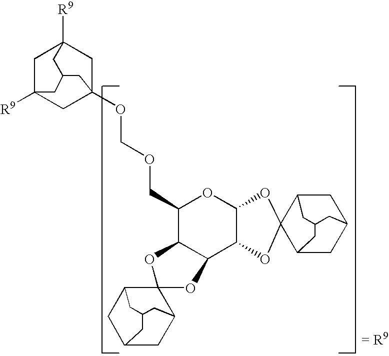

1,3,5-Tris(chloromethoxy)adamantane [2104 mg, 6.38 mmol] and 1,2:3,4-Di-O-(2,2-adamantylidene)-α-D-galactopyranose [8507 mg, 19.14 mmol] were dissolved in dry tetrahydrofuran [150 mL] under nitrogen atmosphere. Triethyl amine [3.5 mL, 25.1 Mmol] was added drop wise, then white precipitation generated gradually. After stirring for 4 days, the reaction was quenched by water. The mixture was added diethyl ether [50 mL] and tetrahydrofuran [50 mL]. The mixture was washed by saturated aqueous NaCl solution [30 mL] three times, and dried over anhydrous Na₂SO₄. The solution was filtered by a paper filter and concentrated. The crude mixture was re-precipitated from chloroform/methanol system, the product was obtained as white powder after drying in vacuo [2683 mg, 1.73 mmol, isolated yield: 27.1%]. ¹H-NMR: 1.49˜2.25 (m, 97H), 3.52˜3.70 (m, 3H), 3.81˜4.01 (m, 6H), 4.24 (d, J=8.0 Hz, 3H), 4.34 (d, J=2.4 Hz, 3H), 4.64 (d, J=7.8 Hz, 3H), 4.76 (d, J=7.6 Hz, 3H), 4.91 (d, J=7.6 Hz, 3H), 5.54 (d, J=4.9 Hz, 3H). ¹³C-NMR: 26.62, 26.80, 26.91, 30.69, 34.04, 34.53, 34.60, 34.89, 35.08, 35.27, 36.92, 37.01, 37.06, 37.26, 39.50, 39.73, 40.33, 45.18, 45.75, 46.46, 51.18, 51.46, 65.82, 66.42, 66.50, 70.07, 70.33, 70.52, 75.74, 75.84, 89.28, 95.83, 111.32, 111.38, 112.02, 112.07.

1,3,5-Tri(2-adamantyloxymethyl)adamantane (Formula GR-10)

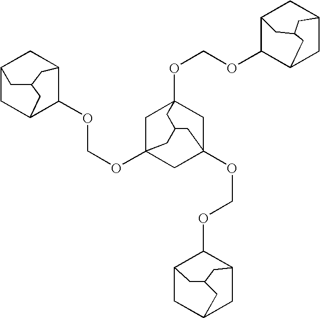

1,3,5-Adamantanetriol [372 mg, 2.0 mmol] was dissolve in dry dimethylformamide [10 mL]. 2-(chloromethoxy)adamantane (“Adamantate AOMC-2” manufactured by Idemitsu Kosan Co., Ltd.) [1325 mg, 6.6 mmol] was added into the solution, then the solution turned to white slurry. Triethyl amine [1.25 mL, 9.0 mmol] was added drop wise, then white precipitation generated immediately. After stirring for 4d, the reaction was quenched by water. The mixture was extracted by diethyl ether [30 mL] three times. The extracted solution was washed by water [30 mL] three times and by saturated aqueous NaCl solution [30 mL] once, and dried over anhydrous K₂CO₃. The solution was filtered by a paper filter and concentrated. The crude mixture was re-precipitated from chloroform/n-hexane system, the product was obtained as white powder after drying in vacuo [261 mg, 0.39 mmol, isolated yield: 19.1%]. ¹H-NMR: 1.39˜2.15 (m, 55H), 3.76 (s, 3H), 4.86 (s, 6H). ¹³C-NMR: 27.24, 27.33, 29.60, 31.53, 31.57, 31.93, 31.96, 32.11, 36.41, 36.57, 40.00, 42.73, 49.14, 51.89, 70.91, 75.89, 78.91, 86.41.

General Properties: To investigate the performance of the disclosed photoresists in 193 nm lithography, each glass resist GR-1 through GR-10 was evaluated and the results are tabulated in FIG. 1. As noted in FIG. 1, each material forms a stable glass at temperatures exceeding room temperature. GR-1, GR-2, GR-5 and GR-9 form stable glasses at temperatures exceeding 100° C. GR-3 and GR-4 were synthesized from mono saccharose such as glucose or galactose and, as a result, show a low T_{g} or oily state because of their asymmetrical core and non-cholic structure. While GR-9 was also made from monosaccharose, the monosaccharose was used as the side air of tripodal structure. As a result, GR-9 shows a high T_{g}.

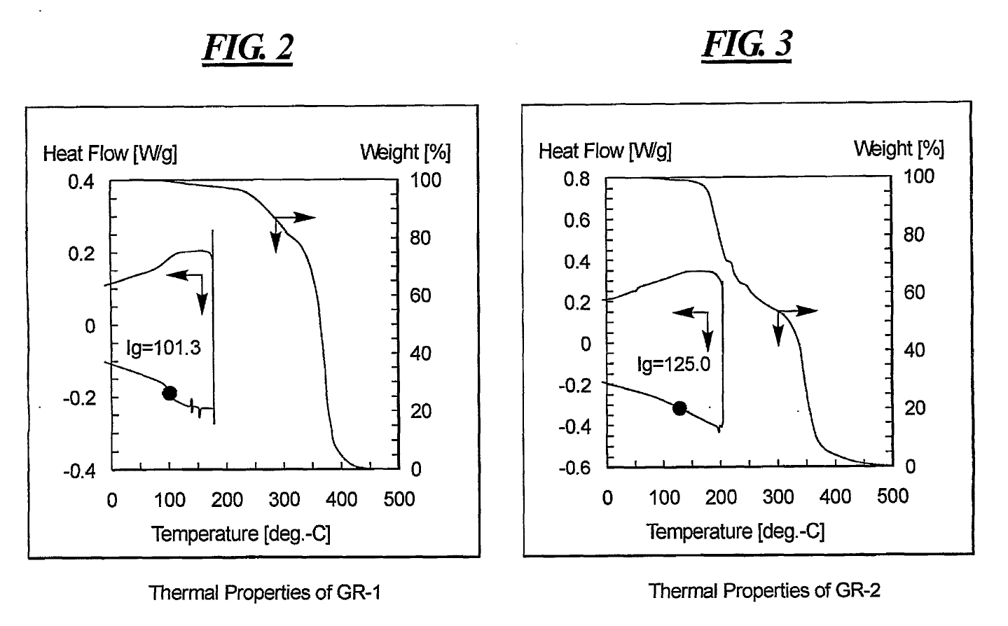

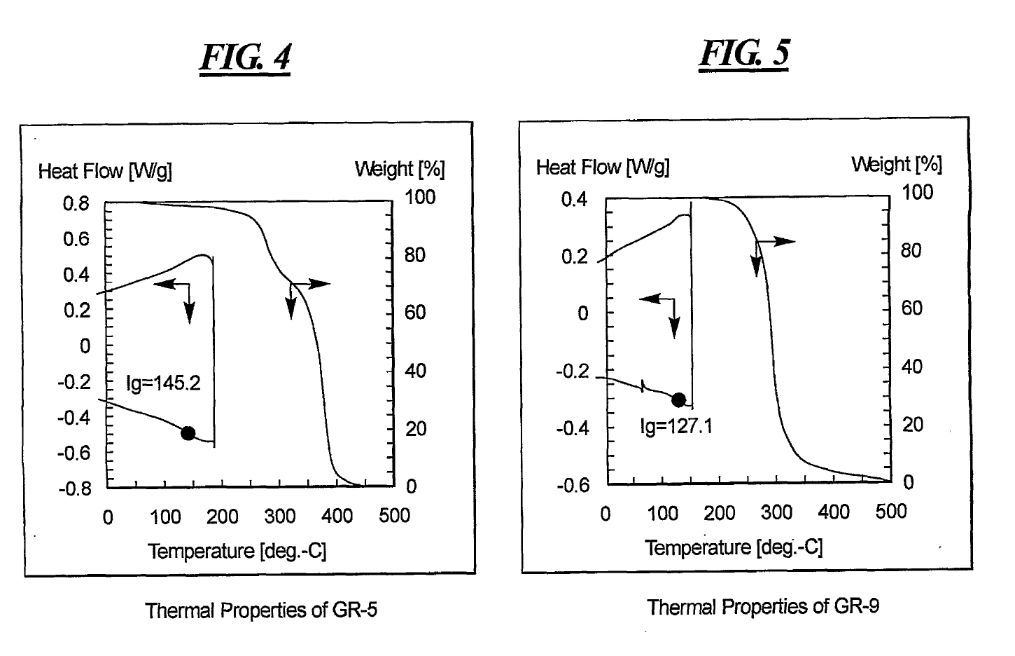

After the examinations of the thermal properties (see the discussion of FIGS. 2-5 below), the solubilities in general solvents for lithography such as propylene glycol monoethyl ether acetate (PGMEA) and ethyl lactate(EL) were evaluated with the results presented in FIG. 1. The solutions of the glass resists including photo acid generator (PAG) were examined the preliminary DUV exposure test, and observed their basic patterning following development in a TMAH solution. The observations of the patterning results are also presented in FIG. 1.

Thermal Properties: The molecular glass resists were examined by differential scanning calorimetry (DSC) and thermo-gravimetric analysis (TGA). Some of the typical DSC and TGA profiles are shown in FIGS. 2 through 5. Weight losses which might be due to their decompositions of the protective group are observed above 150° C. The T_{g} exceeded 100° C. during the second heating.

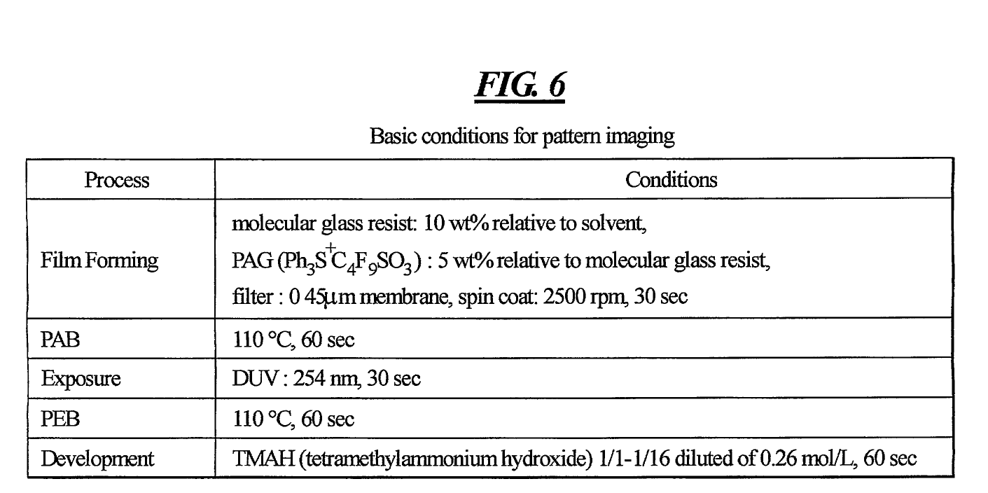

Evaluation of lithography: The condition for the preliminary evaluation of glass resists GR-1 through GR-10 are described to FIG. 6. Each sample wafer was prepared as follows. The filtered solution of glass resist including a photo acid generator (PAG) was applied to a non-primed silicon wafer. After spin coating, the wafer was pre-application baked (PAB) on a hot plate, then exposed by deep UV light source through a test pattern mask. The exposed wafer was post-exposure baked (PEB), and then developed.

All the glass resists that dissolve into a standard solvent such as PGMEA or EL succeeded in their film forming. However, because of the molecular repulsion due to the excess adamantyl protection, GR-3 was difficult to form the film even if hexamethyldisilazane (HMDS) was used as a primer. The standard concentration of TMHA solution as 0.26 mol/L was too strong for some of glass resists. In case of GR-5, 1:16 diluted TMAH solution was the best range of the concentration for the development. Through e-beam lithography, FIG. 7 shows the images of GR-5 that indicated the feature size as small as 200 nm in line/space patterns definitely.

Exposure sensitivity: The exposure sensitivity for GR-5 is reported in FIG. 8. A GR-5 film was connected by the acetal structure as a cleavage bond between adamantane core and the tripodal structure. Due to the big protecting group such as a cholic acid, GR-5 consequently showed the high exposure sensitivity as seen in FIG. 8.

Etch resistance: The disclosed glass resists had been expected higher etch resistance due to the entangled cage structure. The etch rate of GR-1 and GR-5 were examined under the CHF₃/O₂ atmosphere, FIGS. 9-11 show their excellent performance. Furthermore, the correlation between the etch rate and the Ohnishi Parameter is expressed in FIG. 11.

Novel glass resists including adamantane and acetal and/or ester moieties with or without tripodal structures were designed for 193 nm positive tone lithography and synthesized in this work. Several glass resists had the good balance of numerous properties. The tripodal structures with acetal protective groups showed the high exposure sensitivity, the effective etch resistance and the excellent thermal stability. The glass resists were imaged with good resolution by the DUV exposure test and the e-beam lithography.

The foregoing description of the invention is merely illustrative thereof, and it is understood that variations and modification can be made without departing from the spirit of scope of the invention as set forth in the following claims. Further possibilities of structure modifications and process conditions will be apparent to those skilled in the art.

What is claimed:

1. A photoresist material comprising:
a glass comprising an adamantyl group and at least one of an ester group or an acetal group.

2. The photoresist material of claim 1 wherein the glass further comprises at least one cholic group.

3. The photoresist material of claim 1 wherein the glass comprises a plurality of adamantyl groups.

4. The photoresist material of claim 1 wherein the glass comprises a plurality of cholic groups.

5. The photoresist material of claim 1 wherein the glass comprises a plurality of adamantyl groups and a plurality of cholic groups.

6. The photoresist material of claim 1 wherein the glass is selected from the group consisting of:
tri(2-adamantyloxymethyl cholate)-3-yl adamantan-1,3,5-tricarboxylate;
tri{[(2-methyl-2-adamantyl)oxy]carbonylmethyl cholate}-3-yl adamantan-1,3,5-tricarboxylate;
1,2,3,4,6-penta-O-(2-adamanthyloxymethyl)-alpha-D-glucose;
1,2,3,4,6-penta-O-{[(2-methyl-2-adamantyl)oxy]carbonylmethyl}-alpha-D-glucose;
adamantane-1,3,5-triyltris(oxymethylene) tricholate;
adamantane-1,3,5-triyltris(oxymethylene) tri-3-(2-adamantyloxymethoxy)cholate;
tri(2-methyl-2-adamantyl) adamantan-1,3,5-tricarboxylate;
1,3,5-tri[(2-adamantyloxymethyl cholate)-3-oxymethyloxy] adamantane;
1,3,5-tri{[1,2:3,4-Di-O-(2,2-aamantylidene)-alpha-D-galactopyranose]-6-oxymethyloxy}adamantane;
1,3,5-tri(2-adamantyloxymethyl)adamantane; and
mixtures thereof.

7. The photoresist material of claim 1 wherein the glass is synthesized from one or more precursors selected from the group consisting of:
1,3,5-adamantanetricarboxylic acid;
1,3,5-adamantanetricarboxylic acid trichloride;
1,3,5-tris(methylthiomethoxy)adamantane;
1,3,5-tris(chloromethoxy)adamantane;
(2-adamantyloxy)methyl cholate;
[(2-methyl-2-adamanthyl)oxy]carbonylmethyl cholate; and
1,2:3,4-Di-O-(2,2-adamantylidene)-alpha-D-galactopyranose.

8. The photoresist material of claim 1 wherein the adamantyl group comprises a center of a tripodal structure and wherein three legs of the tripodal structure are linked to the center adamantyl group by three ester groups or by three acetal groups.

9. The photoresist material of claim 8 wherein the linking of the ester or acetal groups to the center adamantyl group takes place at 1,3 and 5 positions on the center adamantyl group.

10. The photoresist material of claim 1 wherein an alpha-glucose group comprises a center of a five-leg branch structure and wherein the five legs are linked to the center alpha glucose group by four acetal groups and a fifth acetal group and an oxy group.

11. The photoresist material of claim 1 wherein an alpha-glucose group comprises a center of a five-leg branch structure and wherein the five legs are linked to the center alpha glucose group by four oxycarbonylmethyl groups and a fifth oxycarbonylmethyloxy group.

12. The photoresist material of claim 1 wherein the glass is of a tripod structure having a center adamantyl group of the following formula: 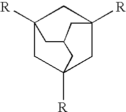
wherein R is selected from the group consisting of: 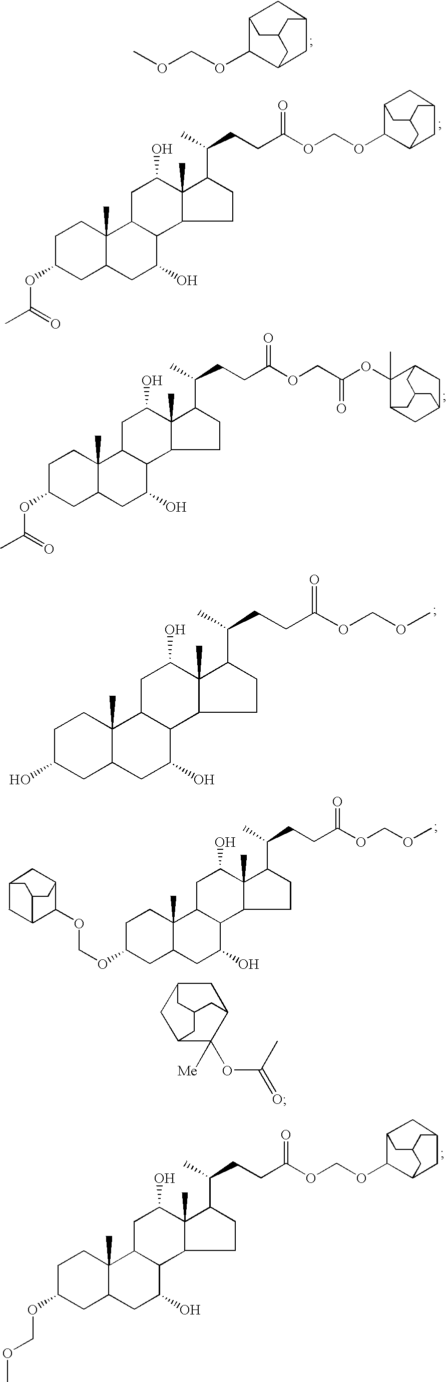 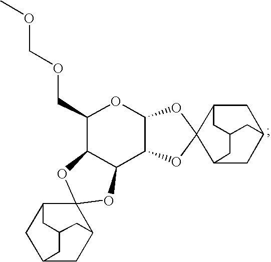
and combinations thereof.

13. The photoresist material of claim 1 further comprising a central alpha-glucose moiety linked at the 1,2,3,4 and 6 by five moieties selected from the group consisting of 2-adamanthyloxymethyl, [(2-methyl-2-adamantyl)oxy]carbonylmethyl and combinations thereof.

14. A method for synthesizing the adamantane based glass photoresist materials of claim 1, the method comprising:
converting 1.3.5-adamantanetriol to 1,3,5-adamantanetricarboxylic acid;
converting 1,3,5-adamantanetricarboxylic acid to 1,3,5-adamantanetricarboxylic acid trichloride,
converting 1,3,5-adamantanetricarboxylic acid trichloride to a tripodal structure with a center adamantyl group by reacting 1,3,5-adamantanetricarboxylic acid trichloride with a reagent selected from the group consisting of:
(2-adamantyloxy)methyl cholate;
[(2-methyl-2-adamanthyl)oxy]carbonylmethyl cholate; and
adamantanol.

15. The method of claim 14 wherein the (2-adamantyloxy)methyl cholate is synthesized by reacting cholic acid with 2-(chloromethoxy)adamantane.

16. The method of claim 14 wherein the [(2-methyl-2-adamanthyl)oxy]carbonylmethyl cholate is synthesized by reacting cholic acid with 2-methyl-2-adamantyl bromoacetate.

17. A method for synthesizing adamantane based glass photoresist materials of claim 1, the method comprising:
converting 1,3,5-adamantanetriol to 1,3,5-tris(methylthiomethoxy)adamantane;
converting 1,3,5-tris(methylthiomethoxy)adamantane to 1,3,5-tris(chloromethoxy)adamantane,
converting 1,3,5-tris(chloromethoxy)adamantane to a tripodal structure with a center adamantyl group by reacting 1,3,5-tris(chloromethoxy)adamantane with a reagent selected from the group consisting of:
cholic acid;
(2-adamantyloxy)methyl cholate; and
1,2:3,4-di-O-(2,2-adamantylidene-alpha-D-galactopyranose.

18. The method of claim 17 wherein the (2-adamantyloxy)methyl cholate is synthesized by reacting cholic acid with 2-(chloromethoxy)adamantane.

19. The method of claim 17 wherein the 1,2:3,4-di-O-(2,2-adamantylidene-alpha-D-galactopyranose is synthesized by reacting 2-admantanone with D-(+)-galactose.

20. The method of claim 17 wherein the reagent is cholic acid to form adamantane-1,3,5-triyltris(oxymethylene) tricholate.

21. The method of claim 20 wherein the adamantane-1,3,5-triyltris(oxymethylene) tricholate is further reacted with 1-(chlormethoxy)adamantane to form adamantane-1,3,5-triyltris(oxymethylene) tri-3-(−2-adamantyloxymethoxy)cholate.

22. The photoresist material of claim 1 synthesized by reacting 1,3,5-adamantanetriol with 2-(chloromethoxy)adamantane to provide 1,3,5-tri(2-adamantyloxymethyl)adamantane.

23. The photoresist material of claim 1 synthesized by reacting D-(+)-glucose with one of 2-methyl-2-adamantyl bromoacetate or 2-(chloromethoxy)adamantane.

24. A process for forming a photoresist pattern, comprising:
coating the photoresist material of claim 1 on a substrate to form a film;
exposing the film to light having a wavelength of less than 200 nm;
developing the exposed photoresist film.

25. The process of claim 22 wherein the wavelength of the light is 193 nm from an ArF laser.
